(19) United States
(12) Patent Application Publication
(10) Pub. No.: US 2022/0377934 A1
(43) Pub. Date: Nov. 24, 2022

(54) HEAT DISSIPATION DEVICE

(71) Applicants: Inventec (Pudong) Technology Corporation, Shanghai (CN); INVENTEC CORPORATION, TAIPEI CITY (TW)

(72) Inventors: Yin-Chang CHENG, TAIPEI CITY (TW); Chi-Zen PENG, TAIPEI CITY (TW); Chia-Chen CHEN, TAIPEI CITY (TW)

(21) Appl. No.: 17/343,759

(22) Filed: Jun. 10, 2021

(30) Foreign Application Priority Data
May 24, 2021 (CN) 202110565301.9

(51) Int. Cl. H05K 7/20; G06F 1/20

(52) U.S. Cl. CPC H05K 7/20145; H05K 7/20154; H05K 7/20172; G06F 1/203

(57) ABSTRACT

A heat dissipation device includes a case, a first board, a second board, a curved supporting structure, and a fan. The first board is disposed in the case. The curved supporting structure has a curved slot which is located on an inner surface of the curved supporting structure, and the curved slot extends radially with respect to a center of the curved supporting structure. The second board is inserted in the curved slot, and the first board, the second board, and the curved supporting structure collectively form an accommodating space. The fan is fixed to the second board and disposed within the accommodating space.

### CROSS-REFERENCE TO RELATED APPLICATION

This application claims priority to China Application Serial Number 202110565301.9, filed May 24, 2021, which is herein incorporated by reference in its entirety.

### BACKGROUND

### Field of Invention

The present invention is related to a heat dissipation device.

### Description of Related Art

Nowadays, the demand for electronic devices such as laptop computer has dramatically increased, and consumers require smaller and thinner products, so as to have more convenient and better product experience. When the electronic devices get lighter and thinner, the accommodating space of the electronic devices which can receive a fan module is decreased, such that the requirement for miniaturizing fan modules is rather important. For improving the heat dissipation efficiency, how to design an airflow guiding structure used in the fan module has become an important issue.

Regarding some electronic devices, the pressure imposed on the case of the electronic devices would lead to malfunction and noise. Therefore, private companies and academic units have spent money, resources, and time on studying the fan module, so as to improve the properties thereof.

### SUMMARY

The present invention provides a heat dissipation device includes a case, a first board, a second board, a curved supporting structure, and a fan. The first board is disposed in the case. The curved supporting structure has a curved slot which is located on an inner surface of the curved supporting structure, and the curved slot extends radially with respect to a center of the curved supporting structure. The second board is inserted in the curved slot, and the first board, the second board, and the curved supporting structure collectively form an accommodating space. The fan is connected to the second board and disposed within the accommodating space.

In one or more embodiments of the present invention, the curved supporting structure includes a plurality of protrusion portions, and airflow channels are respectively defined between any adjacent twos of the protrusion portions, the fan is configured for driving airflows to pass through the airflow channels.

In one or more embodiments of the present invention, the second board comprises a plurality of ventilation holes which surround a position where the fan joins the second board, and the fan is configured for driving airflows to pass through the ventilation holes.

In one or more embodiments of the present invention, the second board includes a plurality of extension arms and a center portion, the extension arms surround the center portion and define the ventilation holes, and the fans is disposed on the center portion.

In one or more embodiments of the present invention, the second board comprises a plurality of ventilation holes which surround a position where the fan joins the second board, and the second board comprises a plurality of ventilation holes which surround a position where the fan joins the second board, the fan is configured for driving airflows to pass through the ventilation holes and then the airflow channels.

In one or more embodiments of the present invention, the second board comprises a plurality of extension arms and a center portion, and the extension arms surround the center portion and define the ventilation holes, the fan is disposed on the center portion.

In one or more embodiments of the present invention, the heat dissipation device further includes a fixing assembly, and the curved supporting structure comprises a fixing hole, the second board comprises a concave edge, the fixing assembly is aligned with and passes through the fixing hole and the concave edge, so as to fix the second board to the curved supporting structure.

In one or more embodiments of the present invention, the curved supporting structure comprises a head portion and a neck portion, and the head portion is farther from the first board than the neck portion, the head portion has a width greater than a width of the neck portion, and the curved slot is disposed at the head portion.

In one or more embodiments of the present invention, the curved supporting structure comprises a bottom portion connected to the first board, and the bottom portion has a width which gradually increases toward the first board.

In one or more embodiments of the present invention, the second board has a sloping side, and the curved supporting structure is U shaped and has a step-shaped end. When the second board in inserted in the curved supporting structure, the sloping side adjoins the step-shaped end for forming an opening.

In one or more embodiments of the present invention, the curved supporting structure and the first board are made from a continuous unitary piece of material.

In embodiments of the present invention, a heat dissipation device which includes a curved supporting structure configured for receiving a board is provided. The curved supporting structure and the board collectively form an accommodating space, and the accommodating space is configured for receiving a fan. Therefore, when the heat dissipation device is pressured, the fan can be protected from malfunction or generating noise by the curved supporting structure and the board.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a schematic view of an electronic device in accordance with some embodiments of the present invention;

FIG. 2 illustrates a schematic view of a heat dissipation device in accordance with some embodiments of the present invention;

FIG. 3 illustrates a top view of a heat dissipation device in accordance with some embodiments of the present invention;

FIG. 4 illustrates a side view of a heat dissipation device in accordance with some embodiments of the present invention;

FIG. 5 and FIG. 6 respectively illustrate two schematic views under two different views in accordance with some embodiments of the present invention;

FIG. 7 illustrates a schematic view of a curved supporting structure in accordance with some embodiments of the present invention; and

FIG. 8 and FIG. 9 illustrate two different enlargement diagrams of the curved supporting structure in FIG. 7.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

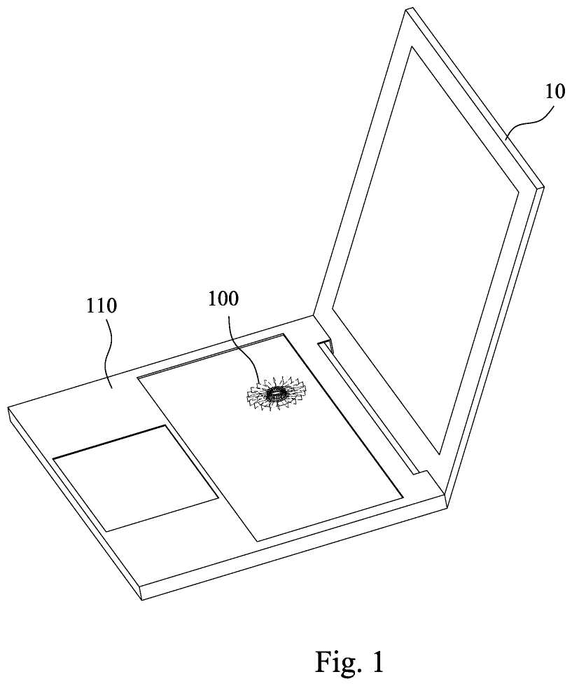

Reference is made to FIG. 1. FIG. 1 illustrates a schematic view of an electronic device 10 in accordance with some embodiments of the present invention, and a heat dissipation device 100 is disposed in the electronic device 10. When the electronic device 10 operates, the heat dissipation device 100 can efficiently control and decrease the temperature of the electronic device 10, so as to prevent the electronic device 10 from overheating and malfunctioning. Moreover, the electronic device 10 can include a mobile phone, a tablet computer, a laptop computer, or a desktop computer. The present invention is not limited in this respect.

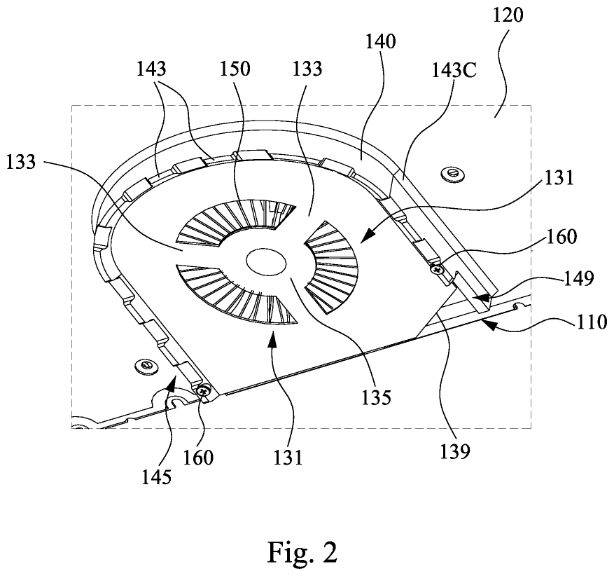

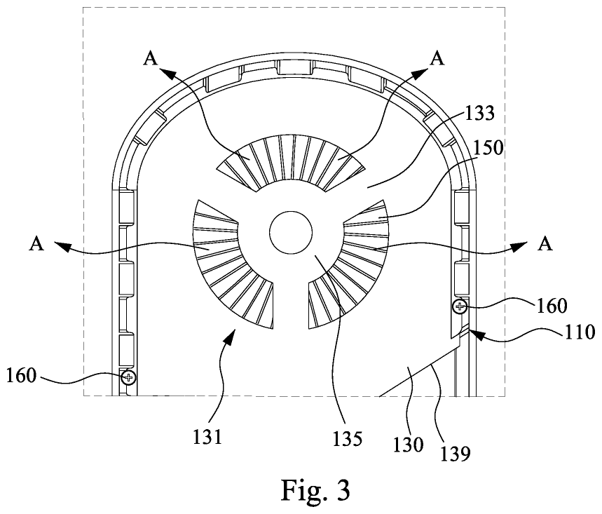

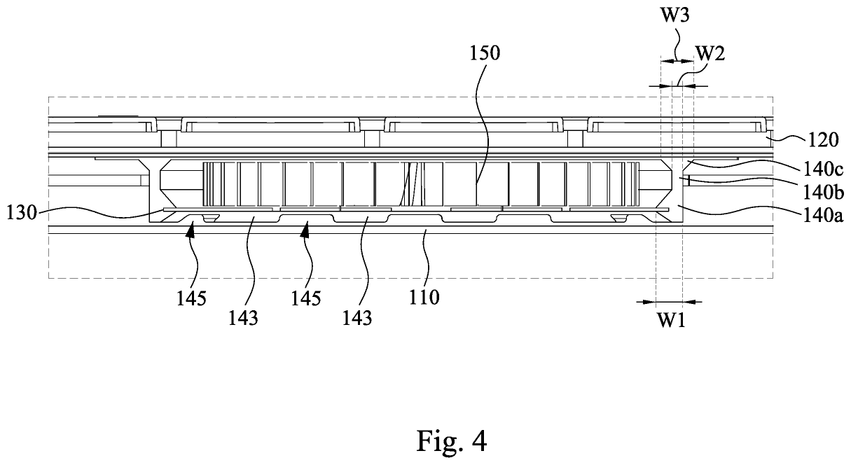

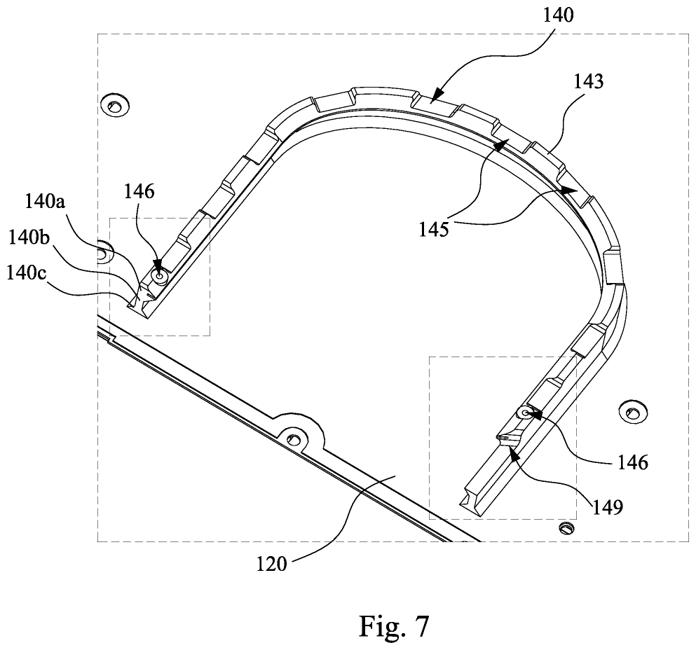

Reference is made to FIGS. 2-4. FIG. 2 illustrates a schematic view of the heat dissipation device 100. FIG. 3 illustrates a top view of the heat dissipation device 100. FIG. 4 illustrates a side view of the heat dissipation device 100. In some embodiments of the present invention, the heat dissipation device 100 includes a case 110, a first board 120, a second board 130, a curved supporting structure 140, and a fan 150, and the case 110 can be made of plastic or metal, such as aluminum alloy and steel. The case 110 can be a part of the electronic device 10, such as a shell of a mobile phone, a shell of a tablet computer, a shell of a laptop computer, or a shell of a desktop computer. The present invention is not limited in this respect. For instance, the electronic device 10 is a laptop computer, and the first board 120 is fixed to and located in the case 110. In some embodiments of the present invention, the first board 120 can be a keyboard bracket of the laptop computer, and the first board 120 and the second board 130 are made of metal such as steel, thereby increasing the mechanical property thereof. The curved supporting structure 140 is substantially U-shaped and fixed to the first board 120, in which the first board 120 and the curved supporting structure 140 can be made from a continuous unitary piece of material. In addition, the curved supporting structure 140 has a curved slot 141 (shown in FIG. 7), the curved slot 141 radially extends with respect to a center C of the curved supporting structure 140, and the curved slot 141 is disposed on an interior surface of the curved supporting structure 140. The curved supporting structure 140 can be made by a variety of processing methods such as stamping process and additive manufacturing process, and the curved slot 141 can be U-shaped and formed by a metal machining process or a laser machining process. Moreover, the fan 150 can be an axial fan or a centrifugal fan for cooling the electronic device 10. The present invention is not limited in this respect.

In some embodiments of the present invention, the second board 130 is inserted in and connected to the curved slot 141, and the first board 120, the second board 130, and the curved supporting structure 140 collectively form an accommodating space S. The fan 150 is fixed to the second board 130 and disposed within the accommodating space S. In addition, the curved supporting structure 140 includes a plurality of protrusion portions 143, and the protrusion portions 143 adjoin an interior surface of the case 110. A plurality of airflow channels 145 are respectively defined between any adjacent twos of the protrusion portions 143, and each airflow channel 145 is disposed between the curved supporting structure 140 and the case 110.

In FIG. 3 and FIG. 4, the airflow channels 145 are respectively disposed among the case 110 and the protrusion portions 143, and the fan 150 is configured for driving airflows A to pass through the airflow channels 145. The second board 130 has a plurality of ventilation holes 131, and the ventilation holes 131 surround the position where the fan 150 joins the second board 130. Moreover, the fan 150 is configured for driving airflows A to pass through the ventilation holes 131. In some embodiments of the present invention, the fan 150 is configured for diving the airflows A to pass through the ventilation holes 131 and then the airflow channels 145. Therefore, the ventilation holes 131 and the airflow channels 145 collectively define paths which the airflows A can pass through, such that the airflows A can efficiently cool the electronic device 10. The present invention is not limited in this respect. Although the airflows A flow from the fan 150 to the ventilation holes 131 and the airflow channels 145, the airflows A might also flow from the ventilation holes 131 and the airflow channels 145 to the fan 150 depending on the category of the fan 150. The present invention is not limited in this respect.

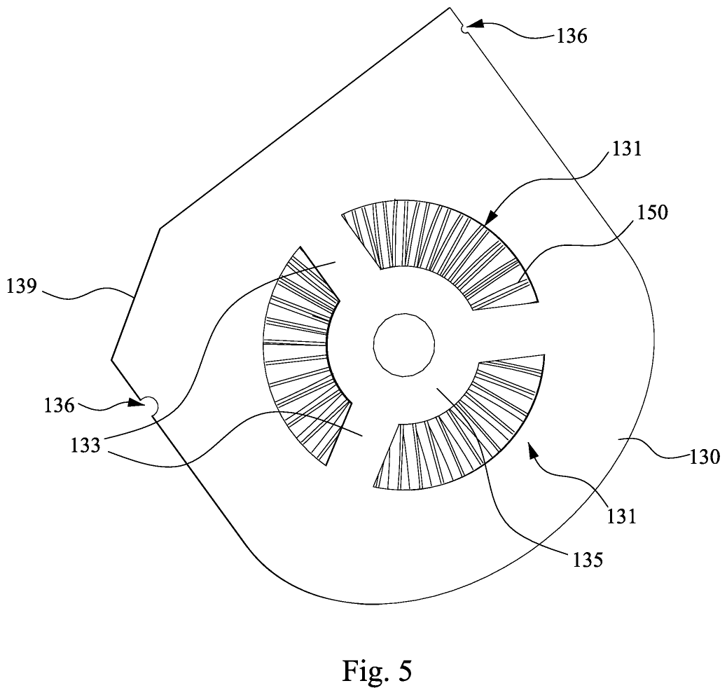

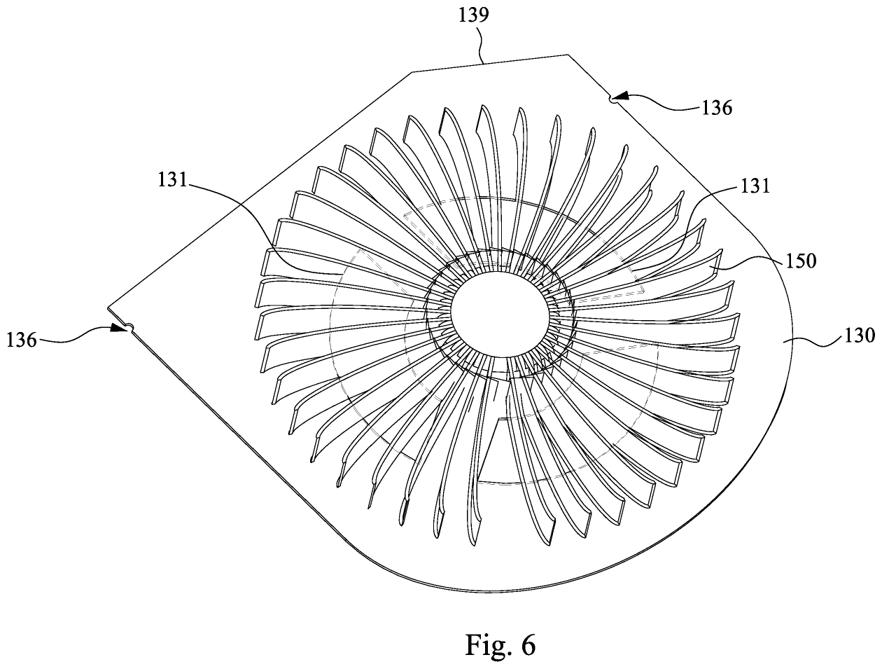

Reference is made to FIGS. 1-6. FIG. 5 and FIG. 6 illustrate schematic views of the second board 130 and the fan 150, in which FIG. 5 and FIG. 6 respectively represent two different views. In some embodiments of the present invention, the second board 130 has a plurality of extension arms 133 and a center portion 135. For instance, second board 130 has three equally spaced extension arms 133 surrounding the center portion 135 and defining the ventilation holes 131 therebetween. The fan 150 is disposed on the center portion 135, and thus the fan 150 can stably and efficiently cool the electronic device 10. Moreover, the center portion 135 is ring-shaped, and the fan 150 is rotatably coupled to the center portion 135. In some embodiments of the present invention, the fan 150 is driven by a motor and rotated in the center portion 135. The present invention is not limited in this respect.

Reference is made to FIGS. 1-7. FIG. 7 illustrates a schematic view of the curved supporting structure 140. In some embodiments of the present invention, the curved supporting structure 140 includes a head portion 140a and a neck portion 140b, in which the head portion 140a is disposed farther from the first board 120 than the neck portion 140b. Moreover, the head portion 140a has a width W1 greater than a width W2 of the neck portion 140b, and the curved slot 141 is located at the head portion 140a, such that the curved supporting structure 140 can stably receive and support the first board 120 by the head portion 140a. The neck portion 140b provides an air flowing space between the curved supporting structure 140 and the second board 130, which is benefit for cooling the electronic device 10 via air convection. The present invention is not limited in this respect.

In some embodiments of the present invention, the curved supporting structure 140 includes a bottom portion 140c, and the bottom portion 140c is directly connected to the first board 120. The bottom portion 140c has a width W3 gradually increasing toward the first board 120, and the bottom portion 140c can be trapezoidal or semi-circular. Thus, the curved supporting structure 140 can be stably connected to the first board 120 via the bottom portion 140c. Moreover, the neck portion 140b is disposed between the head portion 140a and the bottom portion 140c, and the bottom portion 140c has the width W3 equal to or greater than the width W2 of the neck portion 140b. The width W3 of the bottom portion 140c gradually decreases toward the neck portion 140b, which is benefit for cooling the electronic device 10 via air convection. The present invention is not limited in this respect.

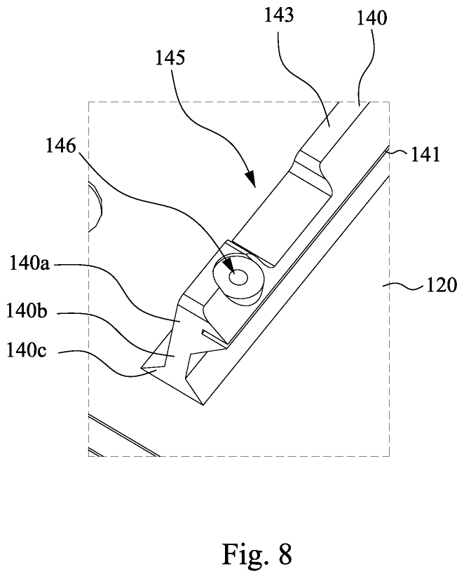

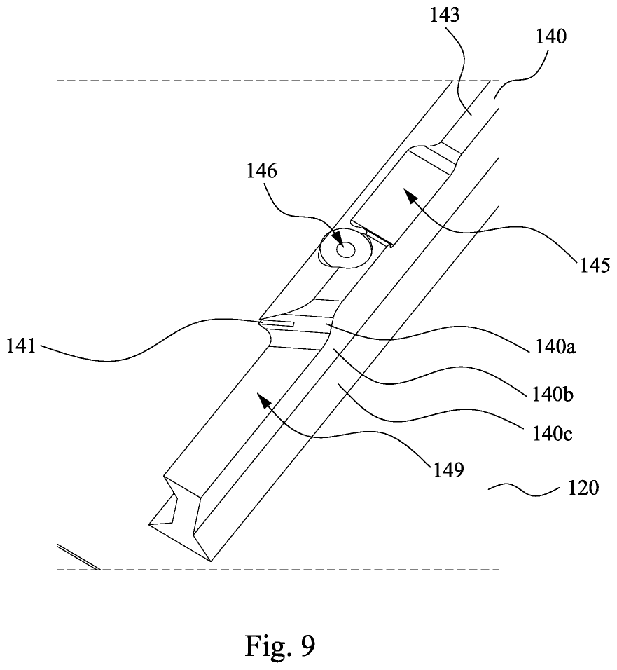

Reference is made to FIGS. 1-9. FIG. 8 and FIG. 9 respectively illustrate enlargement diagrams of the partial curved supporting structure 140 in FIG. 7. In some embodiments of the present invention, the heat dissipation device 100 includes a fixing assembly 160. Moreover, the second board 130 has a concave edge 136, and the curved supporting structure 140 has a fixing hole 146. The fixing assembly 160 is aligned with and passes through the concave edge 136 and the fixing hole 146, such that the second board 130 is stably fixed to the curved supporting structure 140. In some embodiments of the present invention, the fixing hole 146 is a threaded through hole, and the fixing assembly 160 is a screw. The present invention is not limited in this respect.

In some embodiments of the present invention, the second board 130 includes a sloping side 139, and the curved supporting structure 140 is substantially U-shaped and has a step-shaped end 149. When the second board 130 is inserted into the curved supporting structure 140, the sloping side 139 is sloping with and adjoins the step-shaped end 149 to form an opening O. The opening O is convenient for moving the second board 130 in and out of the curved supporting structure 140 by using a tool such as tweezers. The present invention is not limited in this respect.

In embodiments of the present invention, a heat dissipation device which includes a curved supporting structure configured for receiving a board is provided. The curved supporting structure and the board collectively form an accommodating space, and the accommodating space is configured for receiving a fan. Therefore, when the heat dissipation device is pressured, the fan can be protected from malfunction or generating noise by the curved supporting structure and the board.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A heat dissipation device comprising:
a case;
a first board disposed in the case;
a curved supporting structure having a curved slot which is disposed on an inner surface of the curved supporting structure, and the curved slot extends radially with respect to a center of the curved supporting structure;
a second board inserted in the curved slot, wherein the first board, the second board and the curved supporting structure collectively form an accommodating space; and
a fan fixed to the second board and disposed within the accommodating space.

2. The heat dissipation device of claim 1, wherein the curved supporting structure comprises a plurality of protrusion portions, airflow channels are respectively defined between any adjacent twos of the protrusion portions, and the fan is configured for driving airflows to pass through the airflow channels.

3. The heat dissipation device of claim 1, wherein the second board comprises a plurality of ventilation holes which surround a position where the fan joins the second board, the fan is configured to drive airflows to pass through the ventilation holes.

4. The heat dissipation device of claim 3, wherein the second board comprises a plurality of extension arms and a center portion, the extension arms surround the center portion and define the ventilation holes, and the fan is disposed on the center portion.

5. The heat dissipation device of claim 2, wherein the second board comprises a plurality of ventilation holes which surround a position where the fan joins the second board, the second board comprises a plurality of ventilation holes which surround a position where the fan joins the second board, and the fan is configured to drive airflows to pass through the ventilation holes and then the airflow channels.

6. The heat dissipation device of claim 5, wherein the second board comprises a plurality of extension arms and a center portion, the extension arms surround the center portion and define the ventilation holes, and the fan is disposed on the center portion.

7. The heat dissipation device of claim 1, further comprising a fixing assembly, wherein the curved supporting structure comprises a fixing hole, the second board comprises a concave edge, and the fixing assembly is aligned with and passes through the fixing hole and the concave edge, so as to fix the second board to the curved supporting structure

8. The heat dissipation device of claim 1, wherein the curved supporting structure comprises a head portion and a neck portion, the head portion is farther from the first board than the neck portion, and the head portion has a width greater than a width of the neck portion, the curved slot is disposed at the head portion.

9. The heat dissipation device of claim 1, wherein the curved supporting structure comprises a bottom portion connected to the first board, the bottom portion has a width which gradually increases toward the first board.

10. The heat dissipation device of claim 8, wherein the curved supporting structure comprises a bottom portion connected to the first board, the bottom portion has a width which gradually increases toward the first board.

11. The heat dissipation device of claim 1, wherein the second board has a sloping side, the curved supporting structure is U shaped and has a step-shaped end, and the sloping side adjoins the step-shaped end for forming an opening when the second board in inserted in the curved supporting structure.

12. The heat dissipation device of claim 1, wherein the curved supporting structure and the first board are made from a continuous unitary piece of material.
